(19) United States
(12) Patent Application Publication
(10) Pub. No.: US 2025/0336871 A1
(43) Pub. Date: Oct. 30, 2025

(54) SEMICONDUCTOR DEVICE AND METHOD FOR MANUFACTURING SAME

(71) Applicant: Microchip Technology Incorporated, Chandler, AZ (US)

(72) Inventors: Shesh Mani Pandey, Gilbert, AZ (US); Yogesh Kumar Sharma, Colorado Springs, CO (US); George Dorman, Chandler, AZ (US); Randy L. Yach, Phoenix, AZ (US)

(73) Assignee: Microchip Technology Incorporated, Chandler, AZ (US)

(21) Appl. No.: 18/920,214

(22) Filed: Oct. 18, 2024

Related U.S. Application Data
(60) Provisional application No. 63/638,812, filed on Apr. 25, 2024.

(51) Int. Cl. H01L 23/00; H01L 23/538; H01L 25/00; H01L 25/07

(52) U.S. Cl. CPC H01L 24/16; H01L 23/5385; H01L 24/32; H01L 24/48; H01L 24/73; H01L 25/072; H01L 25/50; H01L 2224/16137; H01L 2224/32137; H01L 2224/48227; H01L 2224/73215; H01L 2224/73257

(57) ABSTRACT

A semiconductor device that may include a module. A transistor mounted to the module. A diode mounted to the module, wherein the module is integrated to the transistor.

### CROSS-REFERENCE TO RELATED APPLICATION

The present application claims priority to U.S. Provisional Patent Application No. 63/638,812, filed on Apr. 25, 2024, the contents of which are hereby incorporated by reference in their entirety.

### TECHNICAL FIELD

The present disclosure relates generally to power semiconductor devices, and more specifically to a power semiconductor device having a transistor with an integrated diode, and a method for manufacturing same.

### SUMMARY

According to an aspect of one or more examples, there is provided a semiconductor device that may include a module, a transistor mounted to the module, and a diode mounted to the module, wherein the module is integrated to the transistor. The transistor may be integrated to the diode by a shared terminal. The transistor may be integrated to the diode by a common metal layer. The transistor may be a field effect transistor. The transistor may be a bipolar transistor.

According to an aspect of one or more examples, there is provided a semiconductor device that may include a plurality of modules, at least one transistor mounted to each of at least two of the plurality of modules, and at least one diode mounted to each of the at least two of the plurality of modules, wherein each diode is integrated to each transistor. Each transistor may be integrated to each diode by a shared terminal. Each transistor may be integrated to each diode by a common metal layer. The transistor may be a field effect transistor. The transistor may be a bipolar transistor.

According to an aspect of one or more examples, there is provided a method of manufacturing a semiconductor device. The method may include forming a module, mounting a transistor to the module, and mounting a diode to the module, wherein the diode is integrated to the transistor. The transistor may be integrated to the diode by a shared terminal. The transistor may be integrated to the diode by a common metal layer. The transistor may be a field effect transistor. The transistor may be a bipolar transistor.

According to an aspect of one or more examples, there is provided a method of manufacturing a semiconductor device. The method may include forming a plurality of modules, mounting at least one transistor to each of at least two of the plurality of modules, and mounting at least one diode to each of the at least two of the plurality of modules, wherein each diode is integrated to each transistor. Each transistor may be integrated to each diode by a shared terminal. Each transistor may be integrated to each diode by a common metal layer. The transistor may be a field effect transistor. The transistor may be a bipolar transistor.

### BRIEF DESCRIPTION OF DRAWINGS

FIG. 1A shows a semiconductor device wherein a transistor is integrated to a diode by a shared terminal according to one or more examples.

FIG. 1B shows a semiconductor device wherein a transistor is integrated to a diode by a common metal layer according to one or more examples.

FIG. 2A shows a semiconductor device wherein a transistor is integrated to a diode by a shared terminal according to one or more examples.

FIG. 2B shows a semiconductor device wherein a transistor is integrated to a diode by a common metal layer according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

Wiring a semiconductor device to another semiconductor device may result in failures, switching losses, and additional expense. Therefore, there is a need for a semiconductor device that reduces the need for wiring devices to one another.

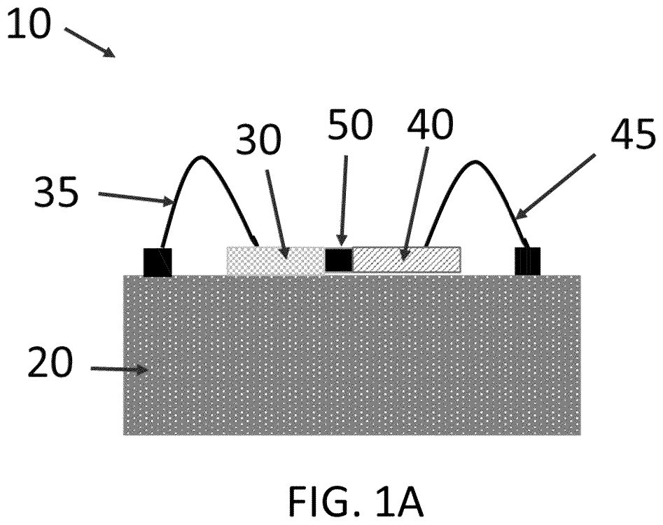

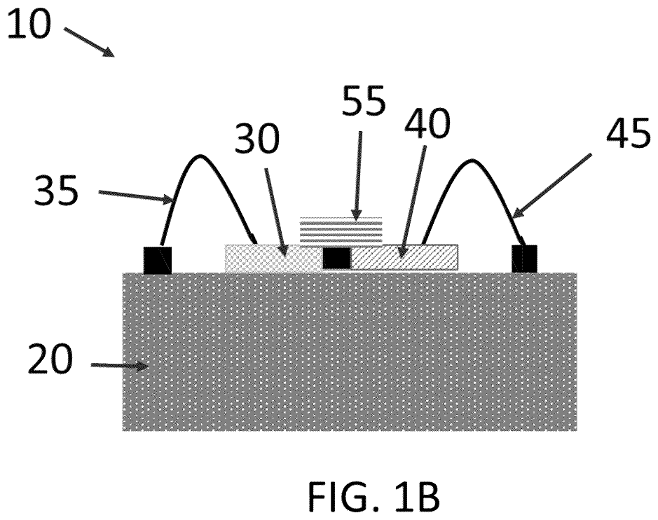

FIG. 1A shows a semiconductor device 10 according to one or more examples. The semiconductor device 10 shown in FIG. 1A may include a module 20. A transistor 30 may be mounted on the module 20. A diode 40 may be mounted on the module 20 and may be integrated to the transistor 30. The transistor 30 may be integrated to the diode 40 by a shared terminal 50. Any type of device, any size of device and any number of devices may be mounted to the module 20 of the semiconductor device shown in FIG. 1A. The semiconductor device 10 shown in FIG. 1A reduces the need to wire bond a diode 40 to a transistor 30. Reducing the need for wire bonding reduces failures but also reduces the area needed for the devices (diode 40 and transistor 30). The transistor 30 may be a field effect transistor, a bipolar transistor and/or any other transistor.

FIG. 1B shows a semiconductor device 10 according to one or more examples. The semiconductor device 10 shown in FIG. 1B may include a module 20. A transistor 30 may be mounted on the module 20. A diode 40 may be mounted on the module 20 and may be integrated to the transistor 30. The transistor 30 may be integrated to the diode 40 by a common metal layer 55. Any type of device, any size of device and any number of devices may be mounted to the module 20 of the semiconductor device shown in FIG. 1B. The semiconductor device 10 shown in FIG. 1B reduces the need to wire bond a diode 40 to a transistor 30. Reducing the need for wire bonding reduces failures but also reduces the area needed for the devices (diode 40 and transistor 30). The transistor 30 may be a field effect transistor, a bipolar transistor and/or any other transistor.

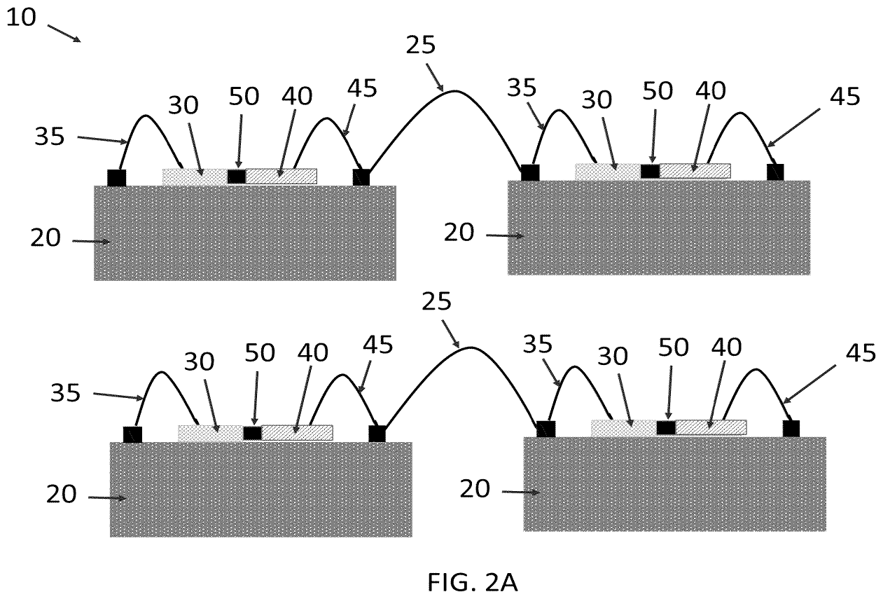

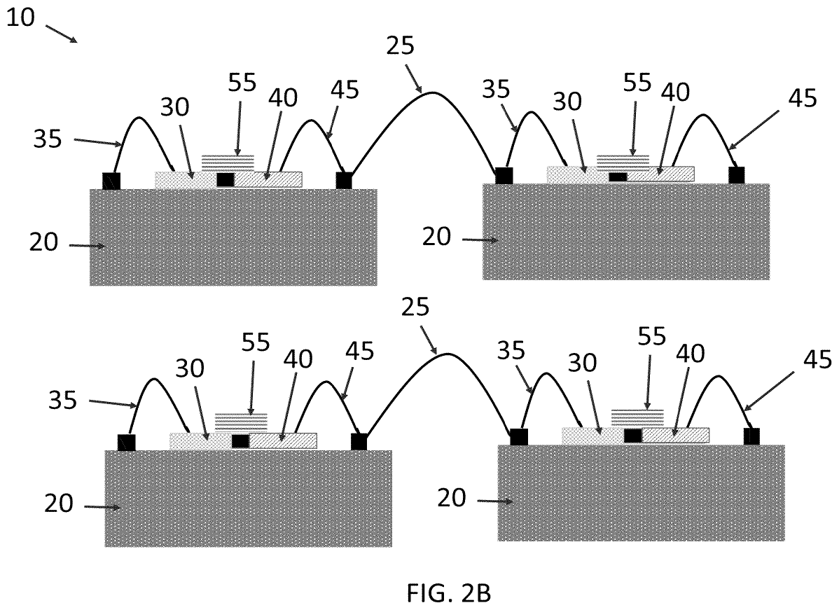

FIG. 2A shows a semiconductor device 10 according to one or more examples. The semiconductor device 10 shown in FIG. 2A may include a plurality of modules 20. At least one transistor 30 may be mounted on each of at least two of the plurality of modules 20. At least one diode 40 may be mounted to each of the at least two of the plurality of modules 20 and each diode 40 may be integrated to each transistor 30. Each transistor 30 may be integrated to each diode 40 by a shared terminal 50. Any type of device, any size of device and any number of devices may be mounted to each of the at least two of the plurality of modules 20 of the semiconductor device shown in FIG. 2A. The semiconductor device 10 shown in FIG. 2A reduces the need to wire bond each diode 40 to each transistor 30. Reducing the need for wire bonding reduces failures but also reduces the area needed for the plurality of devices (diodes 40 and transistors 30). The transistors 30 may be a field effect transistor, a bipolar transistor and/or any other transistor.

FIG. 2B shows a semiconductor device 10 according to one or more examples. The semiconductor device 10 shown in FIG. 2B may include a plurality of modules 20. At least one transistor 30 may be mounted on each of at least two of the plurality of modules 20. At least one diode 40 may be mounted to each of the at least two of the plurality of modules 20 and each diode 40 may be integrated to each transistor 30. Each transistor 30 may be integrated to each diode 40 by a common metal layer 55. Any type of device, any size of device and any number of devices may be mounted to each of the at least two of the plurality of modules 20 of the semiconductor device shown in FIG. 2B. The semiconductor device 10 shown in FIG. 2B reduces the need to wire bond each diode 40 to each transistor 30. Reducing the need for wire bonding reduces failures but also reduces the area needed for the plurality of devices (diodes 40 and transistors 30). The transistors 30 may be a field effect transistor, a bipolar transistor and/or any other transistor.

The semiconductor device 10 of FIG. 1A may be fabricated by forming a module 20. A transistor 30 may be mounted to the module 20. A diode 40 may be mounted to the module 20 and may be integrated to the transistor 30. The transistor 30 may be integrated to the diode 40 by a shared terminal 50. Any type of device, any size of device and any number of devices may be mounted to the module 20 of the semiconductor device 10 shown in FIG. 1A. The semiconductor device 10 shown in FIG. 1A reduces the need to wire bond a diode 40 to a transistor 30. Reducing the need for wire bonding reduces failures but also reduces the area needed for the devices (diode 40 and transistor 30). The transistor 30 may be a field effect transistor, a bipolar transistor and/or any other transistor.

The semiconductor device 10 of FIG. 1B may be fabricated by forming a module 20. A transistor 30 may be mounted to the module 20. A diode 40 may be mounted to the module 20 and may be integrated to the transistor 30. The transistor 30 may be integrated to the diode 40 by a common metal layer 55. Any type of device, any size of device and any number of devices may be mounted to the module 20 of the semiconductor device shown in FIG. 1B. The semiconductor device 10 shown in FIG. 1B reduces the need to wire bond a diode 40 to a transistor 30. Reducing the need for wire bonding reduces failures but also reduces the area needed for the devices (diode 40 and transistor 30). The transistor 30 may be a field effect transistor, a bipolar transistor and/or any other transistor.

The semiconductor device 10 of FIG. 2A may be fabricated by forming a plurality of modules 20. At least one transistor 30 may be mounted to each of at least two of the plurality of modules 20. At least one diode 40 may be mounted to each of the at least two of the plurality of modules 20. Each diode 40 may be integrated to each transistor 30. Each transistor 30 may be integrated to each diode 40 by a shared terminal 50. Any type of device, any size of device and any number of devices may be mounted to the modules 20 of the semiconductor device 10 shown in FIG. 2A. The semiconductor device 10 shown in FIG. 2A reduces the need to wire bond each diode 40 to each transistor 30. Reducing the need for wire bonding reduces failures but also reduces the area needed for the plurality of devices (diodes 40 and transistors 30). The transistors 30 may be a field effect transistor, a bipolar transistor and/or any other transistor.

The semiconductor device 10 of FIG. 2B may be fabricated by forming a plurality of modules 20. At least one transistor 30 may be mounted to each of at least two of the plurality of modules 20. At least one diode 40 may be mounted to each of the at least two of the plurality of modules 20. Each diode 40 may be integrated to each transistor 30. Each transistor 30 may be integrated to each diode 40 by a common metal layer 55. Any type of device, any size of device and any number of devices may be mounted to the modules 20 of the semiconductor device 10 shown in FIG. 2B. The semiconductor device 10 shown in FIG. 2B reduces the need to wire bond each diode 40 to each transistor 30. Reducing the need for wire bonding reduces failures but also reduces the area needed for the plurality of devices (diodes 40 and transistors 30). The transistors 30 may be a field effect transistor, a bipolar transistor and/or any other transistor.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A semiconductor device comprising:
a module;
a transistor mounted to the module; and
a diode mounted to the module, wherein the module is integrated to the transistor.

2. The semiconductor device of claim 1, wherein the transistor is integrated to the diode by a shared terminal.

3. The semiconductor device of claim 1, wherein the transistor is integrated to the diode by a common metal layer.

4. The semiconductor device of claim 1, wherein the transistor comprises a field effect transistor.

5. The semiconductor device of claim 1, wherein the transistor comprises a bipolar transistor.

6. A semiconductor device comprising:
a plurality of modules;
at least one transistor mounted to each of at least two of the plurality of modules; and
at least one diode mounted to each of the at least two of the plurality of modules, wherein each diode is integrated to each transistor.

7. The semiconductor device of claim 6, wherein each transistor is integrated to each diode by a shared terminal.

8. The semiconductor device of claim 6, wherein each transistor is integrated to each diode by a common metal layer.

9. The semiconductor device of claim 6, wherein the transistor comprises a field effect transistor.

10. The semiconductor device of claim 6, wherein the transistor comprises a bipolar transistor.

11. A method of manufacturing a semiconductor device, the method comprising:
forming a module;
mounting a transistor to the module; and
mounting a diode to the module, wherein the diode is integrated to the transistor.

12. The method of claim 11, wherein the transistor is integrated to the diode by a shared terminal.

13. The method of claim 11, wherein the transistor is integrated to the diode by a common metal layer.

14. The method of claim 11, wherein the transistor comprises a field effect transistor.

15. The method of claim 11, wherein the transistor comprises a bipolar transistor.

16. A method of manufacturing a semiconductor device, the method comprising:
forming a plurality of modules;
mounting at least one transistor to each of at least two of the plurality of modules; and
mounting at least one diode to each of the at least two of the plurality of modules, wherein each diode is integrated to each transistor.

17. The method of claim 16, wherein each transistor is integrated to each diode by a shared terminal.

18. The method of claim 16, wherein each transistor is integrated to each diode by a common metal layer.

19. The method of claim 16, wherein the transistor comprises a field effect transistor.

20. The method of claim 16, wherein the transistor comprises a bipolar transistor.
